(19) United States
(12) Patent Application Publication
(10) Pub. No.: US 2012/0241817 A1
(43) Pub. Date: Sep. 27, 2012

(54) SEMICONDUCTOR DEVICE

(75) Inventors: WATARU SAITO, HYOGO-KEN (JP); SYOTARO ONO, HYOGO-KEN (JP); TOSHIYUKI NAKA, KANAGAWA-KEN (JP); SHUNJI TANIUCHI, ISHIKAWA-KEN (JP); MIHO WATANABE, MIYAGI-KEN (JP); HIROAKI YAMASHITA, HYOGO-KEN (JP)

(73) Assignee: KABUSHIKI KAISHA TOSHIBA, TOKYO (JP)

(21) Appl. No.: 13/424,342

(22) Filed: Mar. 19, 2012

(30) Foreign Application Priority Data
Mar. 22, 2011 (JP) 2011-063369

(51) Int. Cl. H01L 29/78

(52) U.S. Cl. 257/192; 257/E29.262

(57) ABSTRACT

According to an embodiment, a semiconductor device includes a first semiconductor layer, a second semiconductor layer, a control electrode, a third semiconductor layer, first and second main electrodes. The second semiconductor layer is provided on the first semiconductor layer, and has a higher impurity concentration than the first semiconductor layer. The control electrode is provided inside a first trench with an insulating film interposed, the first trench reaching the first semiconductor layer from a front surface of the second semiconductor layer. The third semiconductor layer is provided inside a second trench and including SiₓGe₁₋ₓ or SiₓGe_{y}C_{1-x-y}, the second trench reaching the first semiconductor layer from the front surface of the second semiconductor layer and being adjacent to the first trench with the second semiconductor layer interposed. The first main electrode is connected to the first semiconductor layer, and the second main electrode is connected to the third semiconductor layer.

### CROSS-REFERENCE TO RELATED APPLICATIONS

This application is based upon and claims the benefit of priority from Japanese Patent Application No. 2011-063369, filed on Mar. 22, 2011; the entire contents of which are incorporated herein by reference.

### FIELD

Embodiments are related generally to a semiconductor device.

### BACKGROUND

Generally, a power semiconductor device having a top/bottom electrode structure includes electrodes on the upper surface and the lower surface of a chip; and a negative voltage is applied to the upper electrode and a positive voltage is applied to the lower electrode in the off-state.

Generally, in a power semiconductor device having an n-channel structure, an n-type drain layer is provided on the lower electrode; an n-type drift layer is provided on the n-type drain layer; and a p-type base layer (a p-type body layer) in which a channel is formed is provided on the n-type drift layer. An n-type source layer connected to the upper electrode is provided in the front surface of the p-type base layer. A trench is provided from the front surface of the n-type source layer to reach the n-type drift layer by piercing the p-type base layer. A gate electrode is provided inside the trench with a gate insulating film interposed.

In this type of power semiconductor device, the channel density is increased and the on-resistance is reduced by downscaling the trench gate pitch. However, there are limits to such downscaling; and further reduction of the on-resistance has become difficult.

Due to such circumstances, a structure is drawing attention in which a semiconductor layer having a lattice constant that is different from that of the p-type base layer is formed inside the p-type base layer. In the case where the semiconductor layers have mutually different lattice constants, stress is applied to the p-type base layer; the carrier mobility of the p-type base layer increases; and the on-resistance decreases.

However, in this type of power semiconductor device, bipolar action may occur due to the parasitic bipolar transistor made of the n-type drift layer, the p-type base layer, and the n-type source layer. Accordingly, in addition to a low on-resistance, it is necessary for power semiconductor devices having top/bottom electrode structures to have low bipolar action and good breakdown stability.

### BRIEF DESCRIPTION OF THE DRAWINGS

FIGS. 1A and 1B are schematic views of a semiconductor device according to a first embodiment;

FIGS. 2A and 2B illustrate band structures of the semiconductor device;

FIGS. 3A to 4C are schematic cross-sectional views illustrating manufacturing processes of the semiconductor device;

FIG. 5 is a schematic cross-sectional view of a semiconductor device according to a first variation of the first embodiment;

FIG. 6 is a schematic cross-sectional view of a semiconductor device according to a second variation of the first embodiment;

FIG. 7 is a schematic cross-sectional view of a semiconductor device according to a third variation of the first embodiment;

FIG. 8 is a schematic cross-sectional view of a semiconductor device according to a second embodiment; and

FIG. 9 is a schematic cross-sectional view of a semiconductor device according to a third embodiment.

### DETAILED DESCRIPTION

According to one embodiment, a semiconductor device includes a first semiconductor layer of a first conductivity type, a second semiconductor layer of the first conductivity type, a control electrode, a third semiconductor layer of a second conductivity type, a first main electrode and a second main electrode. The second semiconductor layer is provided on the first semiconductor layer, an impurity concentration of the second semiconductor layer being higher than an impurity concentration of the first semiconductor layer. The control electrode is provided inside a first trench with an insulating film interposed, the first trench reaching the first semiconductor layer from a front surface of the second semiconductor layer. The third semiconductor layer is provided inside a second trench and including SiₓGe₁₋ₓ or SiₓGe_{y}C_{1-x-y}, the second trench reaching the first semiconductor layer from the front surface of the second semiconductor layer and being adjacent to the first trench with the second semiconductor layer interposed. The first main electrode electrically connected to the first semiconductor layer, and the second main electrode connected to the third semiconductor layer.

Embodiments will now be described with reference to the drawings. In the description recited below, similar members are marked with like reference numerals; and a description of members once described is omitted as appropriate.

### First Embodiment

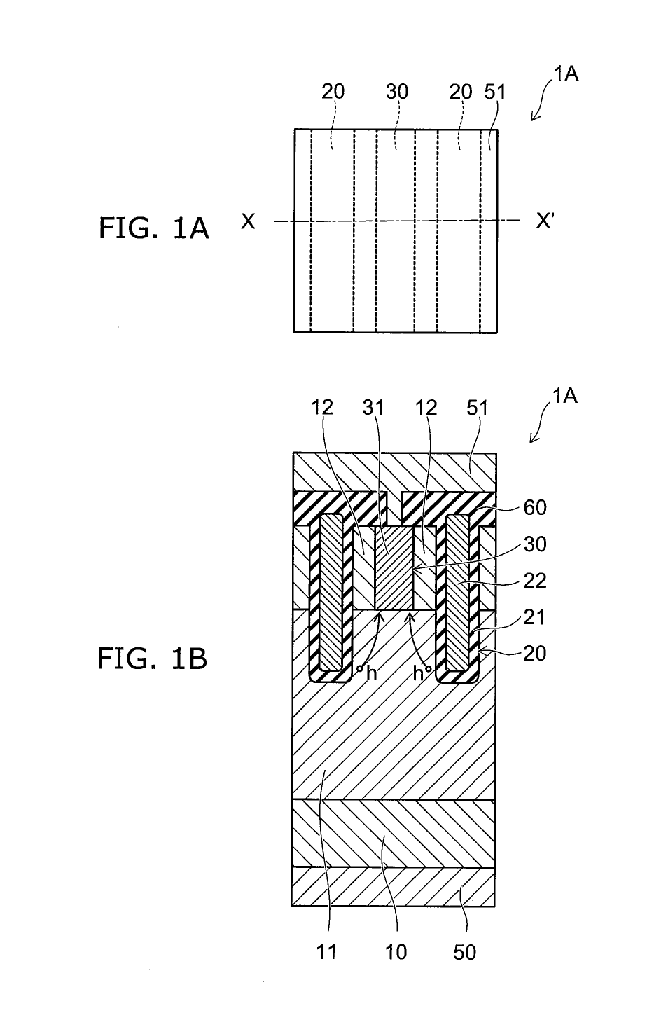

FIGS. 1A and 1B are schematic views of a semiconductor device according to a first embodiment. FIG. 1A is a schematic plan view; and FIG. 1B is a schematic cross-sectional view of position X-X′ of FIG. 1A.

The semiconductor device 1A illustrated in FIGS. 1A and 1B is a power semiconductor device having a top/bottom electrode structure.

In the semiconductor device 1A, an n⁻-type drift layer (a first semiconductor layer) 11 is provided on an n⁺-type drain layer 10. An n⁺-type channel layer (a second semiconductor layer) 12 is provided on the drift layer 11. The impurity concentration of the channel layer 12 is higher than the impurity concentration of the drift layer 11.

In the semiconductor device 1A, a first trench 20 reaches the drift layer 11 from the front surface of the channel layer 12. A gate electrode (a control electrode) 22 is provided inside the first trench 20 with a gate insulating film (an insulating film) 21 interposed.

In the semiconductor device 1A, a second trench 30 reaches the drift layer 11 from the front surface of the channel layer 12. The second trench 30 is adjacent to the first trench 20 with the channel layer 12 interposed. A p-type SiGe-containing layer (a third semiconductor layer) 31 including SiₓGe₁₋ₓ or SiₓGe_{y}C_{1-x-y} (0≦x<1, 0≦y<1, and x>y) is provided inside the second trench 30.

As illustrated in FIG. 1A, the first trench 20 and the second trench 30 are provided in stripe configurations parallel to the front surface of the channel layer 12.

The SiGe-containing layer 31 is adjacent to the channel layer 12. The lower surface of the SiGe-containing layer 31 and the lower surface of the channel layer 12 are in the same plane. In other words, the front surface of the portion of the drift layer 11 other than the first trench 20 is flat; and the SiGe-containing layer 31 and the channel layer 12 are provided on the front surface of the drift layer 11. In other words, the channel layer 12 is provided on the front surface of the drift layer 11 between the SiGe-containing layer 31 and the gate insulating film 21.

A drain electrode (a first main electrode) 50 is connected to the drain layer 10. Accordingly, the drain electrode 50 is electrically connected to the drift layer 11. A source electrode (a second main electrode) 51 is connected to the SiGe-containing layer 31. An inter-layer insulating film 60 is provided between the source electrode 51 and the gate electrode 22, between the source electrode 51 and the channel layer 12, and between the source electrode 51 and a portion of the SiGe-containing layer 31.

The main components of the drain layer 10, the drift layer 11, and the channel layer 12 are, for example, silicon (Si). The material of the gate insulating film 21 is, for example, silicon oxide (SiO₂). The material of the gate electrode 22 is, for example, polysilicon (poly-Si). The material of the drain electrode 50 is, for example, nickel (Ni). The material of the source electrode 51 is, for example, aluminum (Al). In the embodiments, the n⁺ type, the n⁻ type, and the n type are called the first conductivity type; and the p type is called the second conductivity type.

Operations of the semiconductor device 1A will now be described.

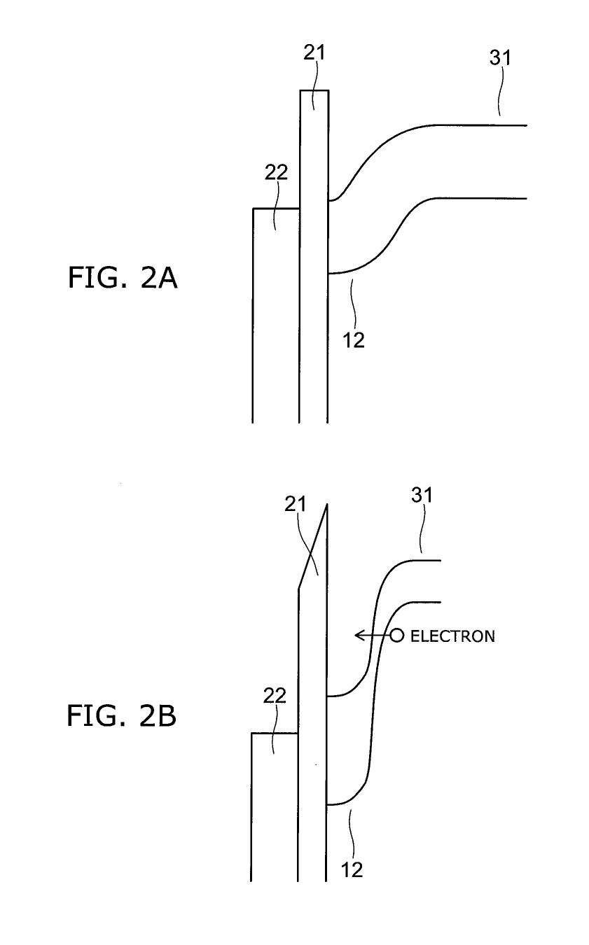

FIGS. 2A and 2B illustrate band structures of the semiconductor device.

FIGS. 2A and 2B illustrate the band structures of the SiGe-containing layer 31, the channel layer 12, the gate insulating film 21, and the gate electrodes 22. FIG. 2A illustrates the state when a bias of the gate electrode 22 is 0 (V); and FIG. 2B illustrates the state when the bias of the gate electrode 22 is the threshold voltage (V). FIG. 2A is the off-state of the semiconductor device 1A; and FIG. 2B is the on-state of the semiconductor device 1A. A voltage is applied between the source electrode 51 and the drain electrode 50 such that the drain electrode 50 side has a positive potential.

A reverse voltage is applied between the SiGe-containing layer 31 and the channel layer 12 by applying the threshold voltage (V) to the gate electrode 22. Thereby, the thickness of the depletion layer is less in FIG. 2B than in FIG. 2A; and a band-to-band tunneling current is generated at the junction interface between the SiGe-containing layer 31 and the channel layer 12. In other words, an electron current flows from the SiGe-containing layer 31 to the channel layer 12 side. The electron current flows through the drift layer 11 to reach the drain layer 10.

Generally, in a conventional MOSFET device having a top/bottom electrode structure, the device is switched to the on-state by forming an inversion channel in the base layer (the body layer). However, in the semiconductor device 1A, the device is switched between the on-state and the off-state by the band-to-band tunneling current being controlled by the potential of the gate electrode 22.

In the semiconductor device 1A, the gate electrode 22 faces the junction interface between the SiGe-containing layer 31 and the channel layer 12. Accordingly, the band-to-band tunneling current flows substantially perpendicular to the direction in which the source electrode 51 faces the drain electrode 50. Thereby, the band-to-band tunneling current is not easily affected by the voltage (the source-drain voltage) applied between the source electrode 51 and the drain electrode 50.

In the semiconductor device 1A, the modulation due to the voltage of the gate electrode 22 can be transmitted efficiently to the junction interface between the SiGe-containing layer 31 and the channel layer 12 as a result of the arrangement in which the gate electrode 22 faces the junction interface where the band-to-band tunneling current is generated. As a result, in the semiconductor device 1A, short channel effects are suppressed. Further, the on/off operations of the semiconductor device 1A can be controlled with high precision by the gate voltage.

In the semiconductor device 1A, the SiGe-containing layer 31 is adjacent to the channel layer 12. In the case where the main component of the channel layer 12 is Si, stress is applied to the channel layer 12 due to the difference between the lattice constants of the SiGe-containing layer 31 and the Si layer. Thereby, the mobility of the carriers inside the channel layer 12 increases. Accordingly, the resistance of the channel layer 12 of the semiconductor device 1A decreases further. As a result, the on-resistance of the semiconductor device 1A decreases further.

Although an n⁺-type source layer and a p-type base layer (a body layer) are provided between the source electrode 51 and the drain layer 10 in a conventional MOSFET, the n⁺-type source layer and the p-type base layer (the body layer) are not provided in the semiconductor device 1A. Therefore, an npn parasitic bipolar transistor does not exist in the semiconductor device 1A. Thereby, the parasitic bipolar transistor does not operate in the semiconductor device 1A. It may also be possible to obtain a high avalanche resistance in the semiconductor device 1A.

The junction between the SiGe-containing layer 31 and the drift layer 11 or between the SiGe-containing layer 31 and the channel layer 12 is a heterojunction. The bandgap of a SiGe-containing layer is narrower than the bandgap of a Si layer. Therefore, a band discontinuity occurs on the valence band side between the SiGe-containing layer 31 and the drift layer 11 or between the SiGe-containing layer 31 and the channel layer 12. The injection of holes (electron holes) into the drift layer 11 or the channel layer 12 from the SiGe-containing layer 31 is suppressed by this band discontinuity of the valence band.

Thereby, in the case where a built-in diode (e.g., the p-type SiGe-containing layer 31/n⁻-type drift layer 11) operates in the semiconductor device 1A, the excessive injection of holes is suppressed; and it becomes possible to reduce the space charge that should be discharged during reverse recovery time. As a result, the recovery loss in the semiconductor device 1A decreases in the switching operation.

In the semiconductor device 1A, even in the case where holes are generated proximally to the lower end of the trench 20 by avalanche breakdown, the holes h are efficiently discharged to the source electrode 51 via the SiGe-containing layer 31 as illustrated by the arrows of FIG. 1B.

Manufacturing processes of the semiconductor device 1A will now be described.

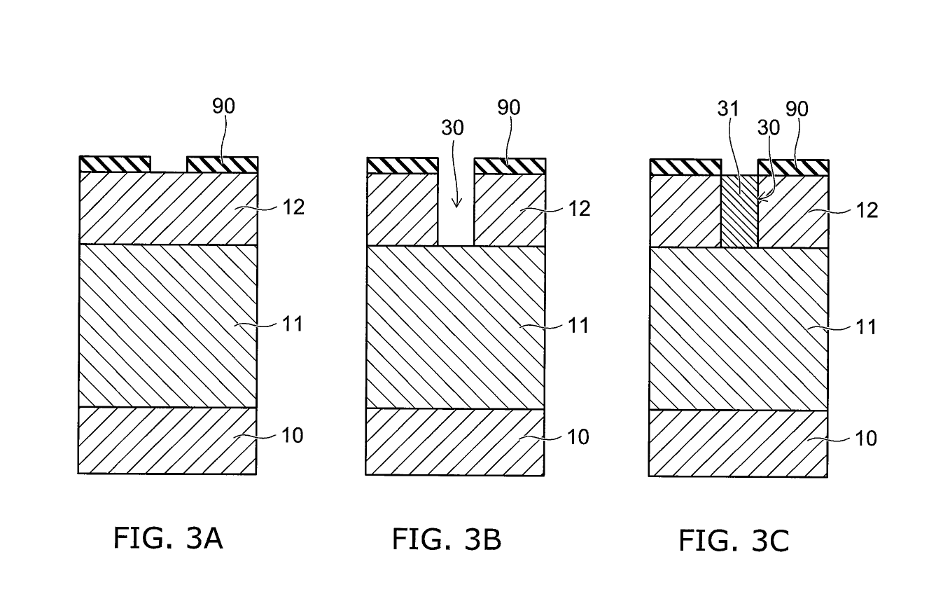

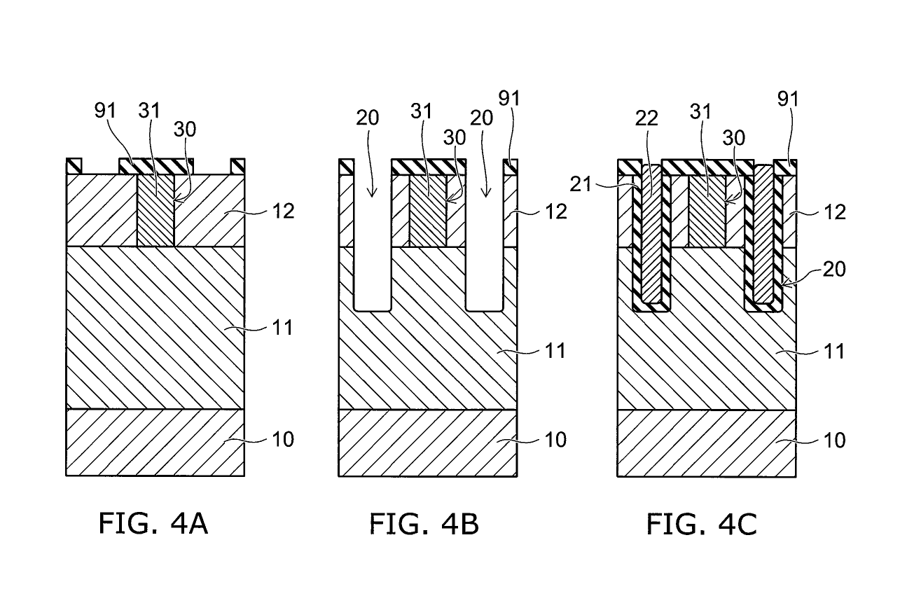

FIGS. 3A to 3C and FIGS. 4A to 4C are schematic cross-sectional views illustrating manufacturing processes of the semiconductor device.

As illustrated in FIG. 3A, a semiconductor stacked body is formed in which the drain layer 10/drift layer 11/channel layer 12 are stacked from the lower layer. The drain layer 10 and the drift layer 11 are formed by, for example, epitaxial growth. The channel layer 12 is formed by, for example, epitaxial growth or ion implantation.

Continuing, a mask member 90 in which an opening is selectively made is formed on the front surface of the channel layer 12. The material of the mask member 90 is, for example, silicon oxide (SiO₂).

Then, as illustrated in FIG. 3B, the channel layer 12 that is exposed from the mask member 90 is etched by, for example, RIE (Reactive Ion Etching). Thereby, the second trench 30 is made.

Continuing as illustrated in FIG. 3C, the SiGe-containing layer 31 is formed inside the second trench 30 by, for example, epitaxial growth. Subsequently, the mask member 90 is removed.

Then, as illustrated in FIG. 4A, a mask member 91 in which an opening is selectively made is formed on the channel layer 12 and on the SiGe-containing layer 31. The material of the mask member 91 is, for example, silicon oxide (SiO₂).

Continuing as illustrated in FIG. 4B, the channel layer 12 that is exposed from the mask member 91 is etched by, for example, RIE (Reactive Ion Etching). Thereby, the first trench 20 is made.

Then, as illustrated in FIG. 4C, the gate insulating film 21 is formed in the first trench 20 by thermal oxidation. The gate electrode 22 is formed on the gate insulating film 21 by CVD (Chemical Vapor Deposition). Subsequently, as illustrated in FIGS. 1A and 1B, the inter-layer insulating film 60, the drain electrode 50, and the source electrode 51 are formed. Thereby, the semiconductor device 1A is formed.

### First Modification of First Embodiment

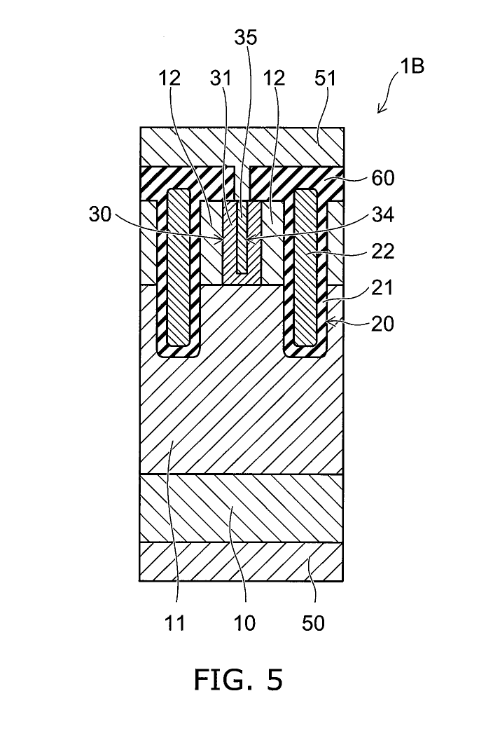

FIG. 5 is a schematic cross-sectional view of a semiconductor device according to a first modification of the first embodiment.

The basic structure of the semiconductor device 1B illustrated in FIG. 5 is the same as that of the semiconductor device 1A. However, in the semiconductor device 1B, a third trench 34 is further provided from the front surface of the SiGe-containing layer 31 into the interior of the SiGe-containing layer 31. A contact layer 35 connected to the second main electrode is provided inside the third trench 34. The contact layer 35 may be a portion of the source electrode 51.

By providing the contact layer 35 having such a trench configuration inside the SiGe-containing layer 31, the contact resistance between the SiGe-containing layer 31 and the source electrode 51 of the semiconductor device 1B is lower than that of the semiconductor device 1A.

### Second Modification of First Embodiment

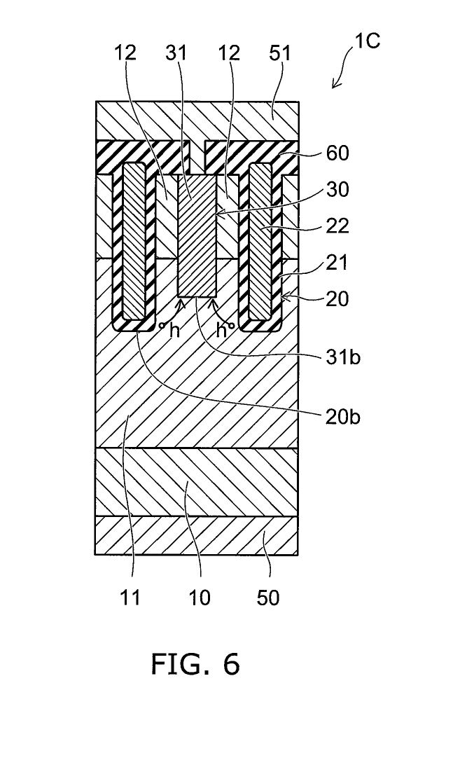

FIG. 6 is a schematic cross-sectional view of a semiconductor device according to a second modification of the first embodiment.

The basic structure of the semiconductor device 1C illustrated in FIG. 6 is the same as that of the semiconductor device 1A. However, in the semiconductor device 1C, a lower end 31b of the SiGe-containing layer 31 is positioned deeper than a lower end 12b of the channel layer 12. The distance between the bottom surface of the SiGe-containing layer 31 and the front surface of the drain layer 10 is shorter than the distance between the bottom surface of the channel layer 12 and the front surface of the drain layer 10.

In the case where the SiGe-containing layer 31 is inserted from the front surface of the drift layer 11 into the interior of the drift layer 11, stress is applied to a portion of the drift layer 11. This is because the lattice constant is different between the SiGe-containing layer 31 and the Si layer in the case where the main component of the drift layer 11 is Si. Thereby, the mobility of the carriers inside the drift layer 11 increases. Accordingly, the resistance of the drift layer 11 of the semiconductor device 1C is lower than the resistance of the drift layer 11 of the semiconductor devices 1A and 1B. As a result, the on-resistance of the semiconductor device 1C is lower than the on-resistances of the semiconductor devices 1A and 1B.

In the semiconductor device 1C, the lower end 31b of the SiGe-containing layer 31 is positioned deeper than the lower end 12b of the channel layer 12. Thereby, in the semiconductor device 1C, the electric field concentration is dispersed between a lower end 20b of the trench 20 and the lower end 31b of the SiGe-containing layer 31. As a result, the breakdown voltage of the semiconductor device 1C is higher than those of the semiconductor devices 1A and 1B.

In the semiconductor device 1C, the hole discharge resistance decreases because the lower end 31b of the SiGe-containing layer 31 is positioned deeper than the lower end 12b of the channel layer 12. Accordingly, the holes h are discharged to the source electrode 51 via the SiGe-containing layer 31 more easily in the semiconductor device 1C than in the semiconductor devices 1A and 1B. As a result, the avalanche energy of the semiconductor device 1C is higher than those of the semiconductor devices 1A and 1B.

### Third Modification of First Embodiment

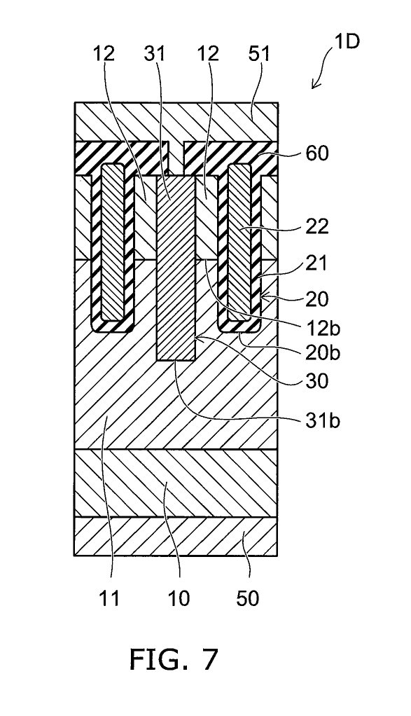

FIG. 7 is a schematic cross-sectional view of a semiconductor device according to a third modification of the first embodiment.

In the semiconductor device 1D illustrated in FIG. 7, the lower end 31b of the SiGe-containing layer 31 is positioned deeper than in the semiconductor device 1C. For example, in the semiconductor device 1D, the lower end 31b of the SiGe-containing layer 31 is positioned deeper than the lower end 20b of the first trench 20. The distance between the bottom surface of the SiGe-containing layer 31 and the front surface of the drain layer 10 is shorter than the distance between the bottom surface of the first trench 20 and the front surface of the drain layer 10.

Thus, in the case where the SiGe-containing layer 31 is formed to a position deeper than the bottom of the first trench 20, the electric field concentration is dispersed between the lower end 20b of the first trench 20 and the lower end 31b of the SiGe-containing layer 31. Thereby, for example, the injection of the hot carriers into the gate insulating film 21 is suppressed; and the gate reliability increases. Further, the holes can be discharged efficiently to the source electrode 51 via the SiGe-containing layer 31 because the location where the avalanche breakdown occurs is proximal to the lower end of the SiGe-containing layer 31. In other words, the avalanche resistance of the semiconductor device 1D is higher than that of the semiconductor device 1C.

In the semiconductor device 1D, the contact surface area between the SiGe-containing layer 31 and the drift layer 11 is greater than that of the semiconductor device 1C. Therefore, more stress is applied to the drift layer 11 of the semiconductor device 1D. As a result, the mobility of the drift layer 11 of the semiconductor device 1D is higher than that of the semiconductor device 1C. In other words, the on-resistance of the semiconductor device 1D is lower than the on-resistance of the semiconductor device 1C.

### Second Embodiment

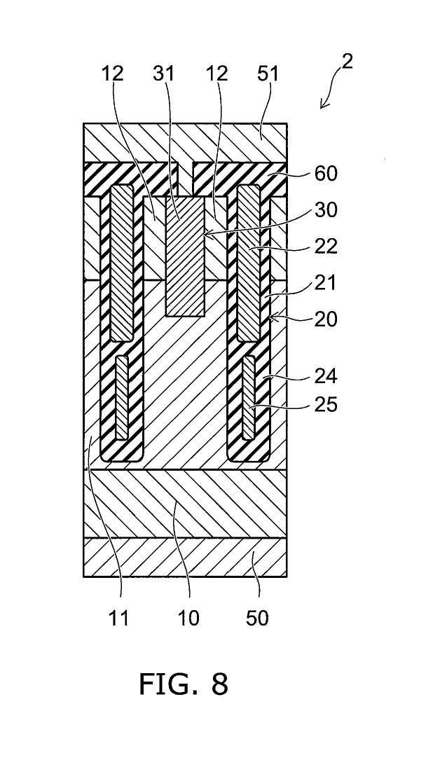

FIG. 8 is a schematic cross-sectional view of a semiconductor device according to a second embodiment.

The basic structure of the semiconductor device 2 illustrated in FIG. 8 is the same as that of the semiconductor device 1B. However, in the semiconductor device 2, a buried electrode 25 is further provided under the gate electrode 22 inside the first trench 20 with an insulating film 24 interposed. The buried electrode 25 is electrically connected to the source electrode 51 or the gate electrode 22. The material of the buried electrode 25 is, for example, polysilicon. The buried electrode 25 functions as a so-called field plate electrode.

Thereby, in the semiconductor device 2, the drift layer 11 is easily depleted via the gate insulating film 21. Therefore, the impurity concentration of the drift layer 11 of the semiconductor device 2 can be set to be higher than the impurity concentration of the drift layer 11 of the semiconductor device 1B. Thereby, the on-resistance of the semiconductor device 2 is lower than the on-resistance of the semiconductor device 1B.

Because the SiGe-containing layer 31 is provided in the semiconductor device 2 as well, the channel layer 12 has low resistance; a high avalanche resistance is realized; and a low recovery loss is realized.

### Third Embodiment

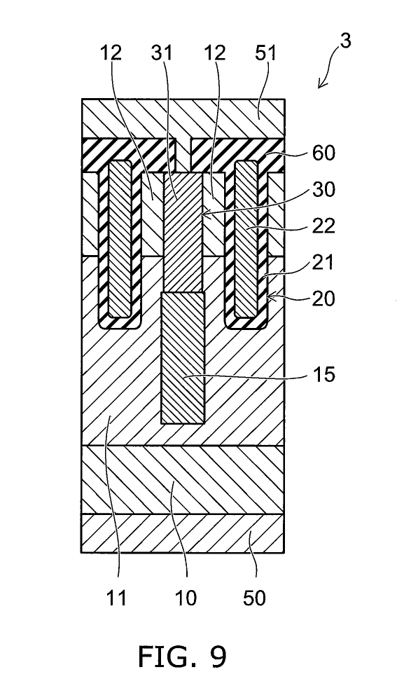

FIG. 9 is a schematic cross-sectional view of a semiconductor device according to a third embodiment.

In the semiconductor device 3 illustrated in FIG. 9, a p-type pillar layer (a fourth semiconductor layer) 15 connected to the SiGe-containing layer 31 is further provided inside the drift layer 11 in addition to the structure of the semiconductor device 1B. The main component of the pillar layer 15 is, for example, silicon (Si). As a result of the pillar layer 15 being provided, the drift layer 11 also has a pillar configuration; and the semiconductor device 3 has a super junction structure in which the drift layer 11 and the pillar layer 15 are alternately arranged on the drain layer 10.

By the pillar layer 15 connected to the SiGe-containing layer 31 being buried inside the drift layer 11, the depletion layer extends from the pillar layer 15 into the drift layer 11; and the drift layer 11 is easily depleted. Therefore, the impurity concentration of the drift layer 11 of the semiconductor device 3 can be set to be higher than the impurity concentration of the drift layer 11 of the semiconductor device 1B. Thereby, the on-resistance of the semiconductor device 3 is lower than the on-resistance of the semiconductor device 1B.

Because the SiGe-containing layer 31 is provided in the semiconductor device 3 as well, the channel layer 12 has low resistance; a high avalanche resistance is realized; and a low recovery loss is realized.

Although the first conductivity type is described as the n type and the second conductivity type is described as the p type in the embodiments, the embodiments are practicable also in the case where the first conductivity type is the p type and the second conductivity type is the n type. Although the terminal structure is not illustrated in the embodiments, the embodiments are not limited by the terminal structure and are practicable using any structure such as RESURF, a field plate, a guard ring, etc.

Regarding the formation process of the super junction structure, the embodiments are practicable using any process such as a process of repeating ion implantation and buried crystal growth, a process of changing the acceleration voltage, etc.

Hereinabove, the embodiments are described with reference to specific examples. However, the embodiments are not limited to these specific examples. In other words, appropriate design modifications made to these specific examples by one skilled in the art also are included in the scope of the embodiments to the extent that the features of the embodiments are included. The components included in the specific examples described above and the dispositions, the materials, the conditions, the configurations, the sizes, and the like of the components included in the specific examples described above are not limited to those illustrated and may be modified appropriately.

The components included in the embodiments described above can be used in combinations within the extent of technical feasibility; and such combinations also are included in the scope of the embodiments to the extent that the features of the embodiments are included. Furthermore, various modifications and alterations within the spirit of the embodiments will be readily apparent to those skilled in the art; and all such modifications and alterations should therefore be seen as within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first semiconductor layer of a first conductivity type;
a second semiconductor layer of the first conductivity type provided on the first semiconductor layer, an impurity concentration of the second semiconductor layer being higher than an impurity concentration of the first semiconductor layer;
a control electrode provided inside a first trench with an insulating film interposed, the first trench reaching the first semiconductor layer from a front surface of the second semiconductor layer;
a third semiconductor layer of a second conductivity type provided inside a second trench and including SiₓGe₁₋ₓ or SiₓGe_{y}C_{1-x-y}, the second trench reaching the first semiconductor layer from the front surface of the second semiconductor layer and being adjacent to the first trench with the second semiconductor layer interposed;
a first main electrode electrically connected to the first semiconductor layer; and
a second main electrode connected to the third semiconductor layer.

2. The device according to claim 1, wherein a third trench is further provided from a front surface of the third semiconductor layer into an interior of the third semiconductor layer, and a contact layer connected to the second main electrode is provided inside the third trench.

3. The device according to claim 2, wherein the contact layer is a portion of the second main electrode.

4. The device according to claim 1, wherein a lower surface of the second semiconductor layer and a lower surface of the third semiconductor layer are included in the same plane.

5. The device according to claim 1, wherein a lower end of the third semiconductor layer is positioned deeper than a lower end of the second semiconductor layer.

6. The device according to claim 1, wherein a lower end of the third semiconductor layer is positioned deeper than a lower end of the first trench.

7. The device according to claim 1, wherein:
a buried electrode is further provided under the control electrode inside the first trench; and
the buried electrode is electrically connected to the second main electrode or the control electrode.

8. The device according to claim 1, wherein a fourth semiconductor layer of the second conductivity type connected to the third semiconductor layer is further provided inside the first semiconductor layer.

9. The device according to claim 8, wherein a super junction structure is provided in the first semiconductor layer.

10. The device according to claim 1, wherein the third semiconductor layer and the control electrode are provided in stripe shape extending in a direction parallel to the front surface of the second semiconductor layer.

11. The device according to claim 1, wherein the first semiconductor layer and the second semiconductor layer are silicon layers.

12. The device according to claim 1, wherein a bandgap of the third semiconductor layer is narrower than a bandgap of the second semiconductor layer.

13. The device according to claim 1, wherein a bandgap of the third semiconductor layer is narrower than bandgaps of the first semiconductor layer and the second semiconductor layer.

14. The device according to claim 1, having discontinuity between a valence band of the third semiconductor layer and a valence band of the first semiconductor layer and between the valence band of the third semiconductor layer and a valence band of the second semiconductor layer.

15. The device according to claim 1, wherein the control electrode is configured to control a band-to-band tunneling current induced between the second semiconductor layer and the third semiconductor layer.

16. The device according to claim 1, wherein a lattice constant of the third semiconductor layer is different from lattice constants of the first semiconductor layer and the second semiconductor layer.
